(19) United States
(12) Patent Application Publication
(10) Pub. No.: US 2016/0320457 A1
(43) Pub. Date: Nov. 3, 2016

(54) BATTERY TESTER DEVICE

(71) Applicant: Robert Avery, Palos Hills, IL (US)

(72) Inventor: Robert Avery, Palos Hills, IL (US)

(21) Appl. No.: 15/140,449

(22) Filed: Apr. 27, 2016

Related U.S. Application Data
(60) Provisional application No. 62/154,562, filed on Apr. 29, 2015.

(51) Int. Cl. G01R 31/36

(52) U.S. Cl. CPC G01R 31/3682; G01R 31/3606

(57) ABSTRACT

A battery tester device for measuring remaining battery life in a battery is provided. The battery tester device comprises a length of wire having a first end, a second end, and a middle portion. A light bulb holding mechanism is formed in the second end of the wire. A light bulb is releasably securable within the light bulb holding mechanism with the light bulb electrically connected to the light bulb holding mechanism. Upon insertion of the battery between the first end and the second end of the wire, the light bulb illuminates to indicate the remaining battery life.

### CLAIM OF PRIORITY

This patent application claims priority under 35 USC 119 (e) (1) from U.S. Provisional Patent Application Ser. No. 62/154,562 filed Apr. 29, 2015, of common inventorship herewith entitled, “Avery's Battery Tester,” which is incorporated herein by reference as though the same were set forth in its entirety.

### FIELD OF THE INVENTION

The present invention pertains to the field of electrical batteries, and more specifically to the field of battery testers.

### BACKGROUND OF THE INVENTION

People like to make sure they do things the best way, be it taking the extra time to wash a car or doing extra research to make sure they are making the right choice on their next vacation destination. People are careful when it comes to investing, eager to make safe but profitable returns. People like to make consumer goods go a long way and often recycle, knowing that continuing to throw away expiring yet renewable products will come back to bite every one financially and environmentally. People drive hybrids, save money, and use their phones for every possible purpose. The practice of conservation is beginning to replace the practice of wastefulness.

People use batteries for everything from flashlights, television remotes, game controllers, kitchen appliances and electric toothbrushes to portable fans, boom boxes, children's toys, cameras, microphones and electric razors. When unsure if a battery has any electrical juice left, a user tends to throw the battery out. As a result, users often throw out batteries that still have life which is a wasteful habit that adds up over time.

The prior art has put forth several designs for battery testers. Among these are:

U.S. Pat. No. 2,142,314 to Floyd F Henriot describes a battery testing clip of simple and effective construction, of great durability, one that is readily applied and removed, wherein the application of the clip in position results in the penetration of any extraneous coating on the terminals, whereby the electrodes or contacting members of the clip are brought into effective engagement with the metal of the battery terminals, thus giving accurate readings. This improved battery testing clip for use in testing batteries has two terminals, one of which is in the form of a post. The aforementioned clip comprises a ring shaped metallic member materially less in thickness than the height of the post and adapted to be forced in a tilted position down over the post so as to make a scraping or wiping contact therewith. A second resilient metallic member connected therewith, but insulated therefrom, makes contact with the other battery terminal and is placed under tension as the first mentioned member is forced down over the post, whereby the ring shaped member is held in engagement with the post by means of its tilting engagement therewith, due to the resilient action of the second member.

U.S. Pat. No. 2,053,353 to Edwin R Talbot describes a storage battery which can be arranged to control an electric circuit to indicate the condition of charge or discharge of the battery, or the loss of liquid from the battery, at a remote point. This invention is particularly applicable to installations wherein the battery is located in an inaccessibly inconvenient location for monitoring the battery charge condition at regular intervals such as in an automobile. A number of floats of different specific gravities are provided in different cells of the battery. One float responds when the specific gravity of the electrolyte in the cell wherein it is located is such as to indicate a fully charged condition. A different float, located in a different cell, is of a specific gravity such that it will respond when the specific gravity in its cell indicates a partially charged condition of the cell, say half charged. Other floats in other cells may respond to specific gravities indicating different fractional charged conditions of the battery. The floats control contacts which are in an electric circuit within an instrument that indicates the condition of the battery and is mounted on a convenient point such as a dashboard of an automobile.

U.S. Pat. No. 1,502,928 to James L Thompson describes a storage battery tester including a shell and a lamp socket carried thereby. An indicating lamp is fitted in the socket. An immersible electrode is coupled with the shell and electrically connected with the socket. A collar surrounds the socket in circuit with the lamp. A cable is connected to the collar and provided with means to co-act with the socket locking the collar in position and a contact electrode connected to the cable.

None of these prior art references describe the present invention.

### SUMMARY OF THE INVENTION

It is an object of the present invention to provide a battery testing device made of a galvanized wire and a bulb that is connectable to a one and one half volt battery and functions to measure the remaining battery life in the battery.

The present invention is a battery tester device for measuring remaining battery life in a battery. The battery tester device comprises a length of wire having a first end, a second end, and a middle portion. A light bulb holding mechanism is formed in the second end of the wire. A light bulb is releasably securable within the light bulb holding mechanism with the light bulb electrically connected to the light bulb holding mechanism. Upon insertion of the battery between the first end and the second end of the wire, the light bulb illuminates to indicate the remaining battery life.

In addition, the present invention includes a method for measuring remaining battery life in a battery. The method comprises providing a length of wire having a first end, a second end, and a middle portion, forming a spring mechanism in the middle portion of the wire, biasing the first end and the second end in a general direction toward each other, forming a light bulb holding mechanism in the second end of the wire, releasably securing a light bulb within the light bulb holding mechanism, electrically connecting the light bulb to the light bulb holding mechanism, inserting the battery between the first end and the second end of the wire, and illuminating the light bulb to indicate the remaining battery life.

The present invention further includes a battery tester device for measuring remaining battery life in a battery. The battery tester device comprises a length of wire having a first end, a second end, and a middle portion. A spring mechanism is formed in the middle portion of the wire for biasing the first end and the second end in a general direction toward each other. A light bulb holding mechanism is formed in the second end of the wire. A light bulb is releasably securable within the light bulb holding mechanism with the light bulb electrically connected to the light bulb holding mechanism. The first end of the wire has a first bend portion bent approximately ninety (90°) degrees relative to the middle portion of the wire and a second bend portion bent approximately an additional ninety (90°) degrees relative to the first bend portion. The second end of the wire has a third bend portion bent approximately ninety (90°) degrees relative to the middle portion. Upon insertion of the battery between the first end and the second end of the wire, the light bulb illuminates to indicate the remaining battery life.

### BRIEF DESCRIPTION OF THE DRAWINGS

FIG. 1 is a perspective view illustrating a battery tester device, constructed in accordance with the present invention, showing a wire extending upward into a spring coiled handle and continuing to extend upward and laterally into a spring coiled holder for a light bulb and its electrically wired housing.

FIG. 2 is another perspective view illustrating the battery tester device, constructed in accordance with the present invention, showing a one and one half volt battery inserted in the battery tester device for testing purposes.

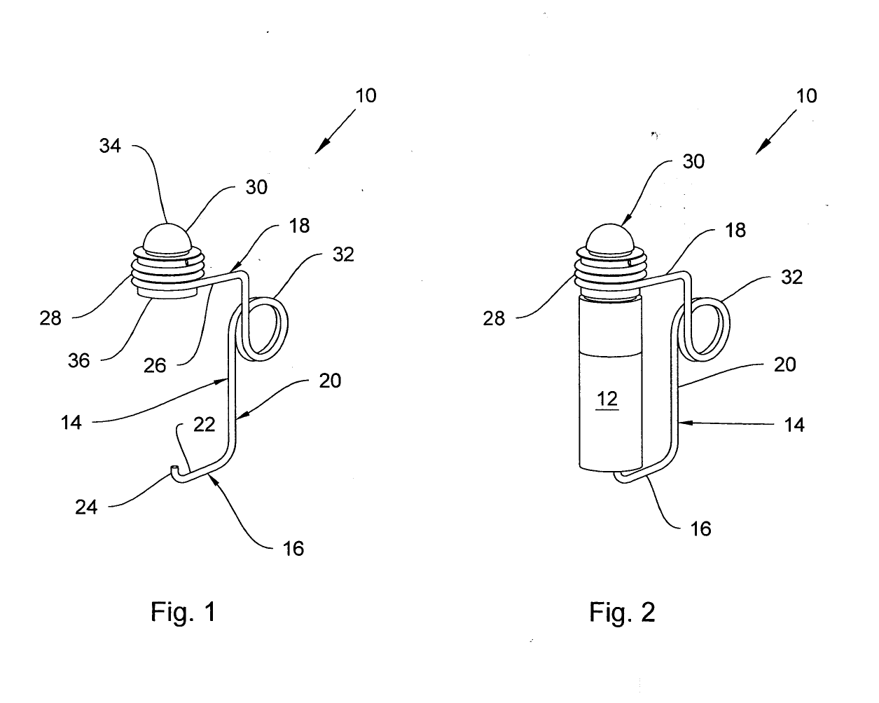

### DETAILED DESCRIPTION OF THE INVENTION

The present invention, hereinafter referred to as a Battery Tester Device, indicated generally at 10, for measuring the remaining battery life in a battery 12. Easily portable in a user's hand or pocket, the Battery Tester Device 10 functions simply, quickly and effectively to measure batteries 12 that the user suspects to be low on electrical power.

The Battery Tester Device 10 of the present invention includes a length of wire 14 having a first end 16, a second end 18, and a middle portion 20. In a preferred embodiment, the wire 14 is constructed from a galvanized metal material and has a length of approximately three and one quarter (3¼″) inches. It should be noted, however, that it is within the scope of the present invention for the wire 14 to be constructed from any type of electrically conductive material and have a length greater than or less than three and one quarter (3¼″) inches.

Preferably, the first end 16 of the wire 14 of the Battery Tester Device 10 of the present invention has a first bend portion 22 bent approximately ninety (90°) degrees relative to the middle portion 20 of the wire 14. The first end 16 of the wire 14 further has a second bend portion 24 bent approximately an additional ninety (90°) degrees relative to the first bend portion 22 in a general direction toward the second end 18 of the wire. In a preferred embodiment, the middle portion 20, the first bend portion 22, and the second bend portion 24 are in the same plane. It should be noted that while the first bend portion 22 and the second bend portion 24 of the first end 16 of the wire 14 are described and illustrated as being ninety (90°) degrees relative to the middle portion 20 and each other, respectively, it is within the scope of the present invention for the first bend portion 22 and/or the second bend portion 24 of the first end 16 of the wire 14 to be bent at an angle greater than or less than ninety (90°) degrees.

The second end 18 of the wire 14 of the Battery Tester Device 10 of the present invention has a first bend portion 26 bent approximately ninety (90°) degrees relative to the middle portion 20 and parallel to the first bend portion 22 of the first end 16 of the wire 14. In addition, the second end 18 of the wire 14 has a coil bulb spring 28 formed therein for receiving a light bulb 30, as will be described in further detail below. It should be noted that while the first bend portion 26 of the second end 18 of the wire 14 has been described and illustrated as being bent approximately ninety (90°) degrees, it is within the scope of the present invention for the first bend portion 26 of the second end 18 of the wire 14 to be bent greater than or less than ninety (90°) degrees.

The middle portion 20 of the wire 14 of the Battery Tester Device 10 of the present invention has a coil wire spring 32 formed therein biasing the first end 16 and the second end 18 of the wire 14 in a general direction toward each other. The coil wire spring 32 allows the first end 16 and the second end 18 of the wire 14 to be moved away from each other to insert the battery 12 to be tested between the first end 16 of the wire 14 and the light bulb 30, as will be described in further detail below. It should be noted that while the coil wire spring 32 has been described as being formed in the middle portion 20 of the wire 14, it is within the scope of the present invention for the coil wire spring 32 to be a separate spring mounted within a break in the middle portion 20 of the wire 14.

As stated above, the light bulb 30 of the Battery Tester Device 10 of the present invention is releasably secured within the coil bulb spring 28. The light bulb 30 has a bulb 34 and a bulb housing 36. The bulb housing 36 is preferably constructed from an electrically conductive material with the bulb housing 36 electrically contacting the bulb 34, and the bulb 34 electrically contacting the battery 12 thus allowing an electrical circuit to be completed between the second end 18 of the wire 14, the bulb housing 36, the bulb 34, and the battery 12 positioned between the first end 16 of the wire 14 and the light bulb 30 thereby completing an electrical circuit. If there is any remaining life in the battery 12 being tested, the light bulb 30 will illuminated indicating the amount of life remaining. The light bulb 30 glows in accordance with how much juice or power is left in the battery 12. The light bulb 30 is preferably colored and transparent to permit even the faintest glow of light produced by the battery 12 to shine from the light bulb 30. The weaker the battery 12, the dimmer the light bulb 30 shines. The stronger the battery 12, the brighter the light bulb 30 shines.

By placing the ends of a battery 12 to the galvanized wire of the Battery Tester Device 10 of the present invention, the user sees an immediate, visual cue of the remaining battery life. Unless the battery 12 is completely drained, the small light bulb 30 glows when a battery 12 is attached to the present invention. The glow intensity of the light bulb 30 corresponds directly to the amount of power remaining in the battery 12. If the battery 12 is full or nearly full, the light bulb 30 glows brightly, indicating the battery 12 has many hours of electrical power left in it. If the battery 12 is low or very low, the light bulb 30 glows dimly and poorly, indicating the battery 12 has little to almost no electrical power left in it and needs to be replaced in the near or immediate future.

The Battery Tester Device 10 of the present invention is an excellent tool for anyone with a drawer full of used batteries 12, appliances and children's toys that run on batteries 12, or stray batteries 12 found under tables and behind sofas. The Battery Tester Device 10 is an excellent tool for individuals who work regularly with electronic equipment such as microphones, portable lights, and recorders. For people who rely on batteries to get their work done, a dead battery can mean that they lose everything. On the other hand, throwing out batteries 12 that are still useful can incur a substantial loss of resources and money over the long run.

Although this invention has been described with respect to specific embodiments, it is not intended to be limited thereto and various modifications which will become apparent to the person of ordinary skill in the art are intended to fall within the spirit and scope of the invention as described herein taken in conjunction with the accompanying drawings and the appended claim.

1. A battery tester device for measuring remaining battery life in a battery, the battery tester device comprising:
a length of wire having a first end, a second end, and a middle portion;
a light bulb holding mechanism formed in the second end of the wire; and
a light bulb releasably securable within the light bulb holding mechanism, the light bulb electrically connected to the light bulb holding mechanism;
wherein upon insertion of the battery between the first end and the second end of the wire, the light bulb illuminates to indicate the remaining battery life.

2. The battery tester device of claim 1 wherein the wire is constructed from a galvanized metal material.

3. The battery tester device of claim 1 wherein the first end of the wire has a first bend portion bent approximately ninety (90°) degrees relative to the middle portion of the wire.

4. The battery tester device of claim 3 wherein the first end of the wire has a second bend portion bent approximately an additional ninety (90°) degrees relative to the first bend portion.

5. The battery tester device of claim 4 wherein the middle portion, the first bend portion, and the second bend portion are in the same plane.

6. The battery tester device of claim 1 wherein the second end of the wire has a first bend portion bent approximately ninety (90°) degrees relative to the middle portion.

7. The battery tester device of claim 1 wherein the bulb holding mechanism is a coil bulb spring for receiving the light bulb.

8. The battery tester device of claim 1 and further comprising:
a spring mechanism mounted in the middle portion of the wire for biasing the first end and the second end in a general direction toward each other.

9. The battery tester device of claim 8 wherein the spring mechanism is a coil wire spring formed from the wire in the middle portion of the wire.

10. The battery tester device of claim 1 wherein the light bulb has a bulb and a bulb housing, the bulb housing being constructed from an electrically conductive material, the bulb housing electrically contacting the bulb, and the bulb electrically contacting the battery thus allowing an electrical circuit to be completed between the second end of the wire, the bulb housing, the bulb, and the battery positioned between the first end of the wire and the light bulb thereby completing an electrical circuit.

11. The battery tester device of claim 1 wherein the glow intensity of the light bulb is in accordance with life remaining in the battery.

12. The battery tester device of claim 2 wherein the light bulb is colored and transparent.

13. A method for measuring remaining battery life in a battery, the method comprising:
providing a length of wire having a first end, a second end, and a middle portion;
forming a spring mechanism in the middle portion of the wire;
biasing the first end and the second end in a general direction toward each other;
forming a light bulb holding mechanism in the second end of the wire;
releasably securing a light bulb within the light bulb holding mechanism;
electrically connecting the light bulb to the light bulb holding mechanism;
inserting the battery between the first end and the second end of the wire; and
illuminating the light bulb to indicate the remaining battery life.

14. A battery tester device for measuring remaining battery life in a battery, the battery tester device comprising:
a length of wire having a first end, a second end, and a middle portion;
a spring mechanism formed in the middle portion of the wire for biasing the first end and the second end in a general direction toward each other;
a light bulb holding mechanism formed in the second end of the wire; and
a light bulb releasably securable within the light bulb holding mechanism, the light bulb electrically connected to the light bulb holding mechanism;
wherein the first end of the wire has a first bend portion bent approximately ninety (90°) degrees relative to the middle portion of the wire;
wherein the first end of the wire has a second bend portion bent approximately an additional ninety (90°) degrees relative to the first bend portion;
wherein the second end of the wire has a third bend portion bent approximately ninety (90°) degrees relative to the middle portion; and
wherein upon insertion of the battery between the first end and the second end of the wire, the light bulb illuminates to indicate the remaining battery life.

15. The battery tester device of claim 14 wherein the middle portion, the first bend portion, the second bend portion, and the third bend portion are in the same plane.

16. The battery tester device of claim 14 wherein the bulb holding mechanism is a coil bulb spring for receiving the light bulb.

17. The battery tester device of claim 14 wherein the spring mechanism is a coil wire spring formed from the wire in the middle portion of the wire.

18. The battery tester device of claim 14 wherein the light bulb has a bulb and a bulb housing, the bulb housing being constructed from an electrically conductive material, the bulb housing electrically contacting the bulb, and the bulb electrically contacting the battery thus allowing an electrical circuit to be completed between the second end of the wire, the bulb housing, the bulb, and the battery positioned between the first end of the wire and the light bulb thereby completing an electrical circuit.

19. The battery tester device of claim 14 wherein the glow intensity of the light bulb is in accordance with life remaining in the battery.

20. The battery tester device of claim 14 wherein the light bulb is colored and transparent.
